(19) United States
(12) Patent Application Publication
(10) Pub. No.: US 2005/0166115 A1
(43) Pub. Date: Jul. 28, 2005

(54) Method for performing software stress test

(76) Inventors: Stefan Daume, Erfurt (DE); Michael George Norman, Edinburgh (GB)

Correspondence Address: FAY KAPLUN & MARCIN, LLP;Suite 702, 150 Broadway, New York, NY, 10038, US

(21) Appl. No.: 10/762,794

(22) Filed: Jan. 22, 2004

(51) Int. Cl. G06F 11/00; G01R 31/28

(52) U.S. Cl. 714/741

(57) ABSTRACT

Described is a method for generating a usage task from usage data, constructing a pattern graph from the usage task, constructing a model graph which represents a space of equivalents to the usage task represented by the pattern graph and extracting sub-graphs from the model graph, wherein each of the extracted sub-graphs is isomorphic to the pattern graph.

### BACKGROUND

Conventional software applications usually require load or stress tests, which simulate situations during which multiple users are simultaneously utilizing the software. Load tests provide important analytical information regarding the stability of the application which they are designed to test. Therefore, it is highly desirable for load tests to be performed on applications that are generally utilized by a plurality of users (e.g., databases, webservers, etc.). If those applications are not subjected to load tests, then they may fail at a crucial point (i.e., if too many users are attempting to use the application), which may result in irreparable downtime for the application.

There are a number of scalability issues in performing load tests. For example, the amount of hardware required to allow a thousand users to simultaneously work with the application can be overwhelming, hence such an actual load test is not a desired option. Therefore, there are special methods of simulating an actual load test by using specialized software. However, to simulate a stress test, a record of actual user interactions with the application is required.

### SUMMARY OF THE INVENTION

A method for generating a usage task from usage data, constructing a pattern graph from the usage task, constructing a model graph which represents a space of equivalents to the usage task represented by the pattern graph and extracting sub-graphs from the model graph, wherein each of the extracted sub-graphs is isomorphic to the pattern graph.

Furthermore, a system, comprising a pattern graph construction module configured to construct a pattern graph from a usage task, a model graph construction module configured to construct a model graph which represents a space of equivalents to the usage task represented by the pattern graph and an extraction module configured to extract sub-graphs from the model graph, wherein each of the extracted sub-graphs is isomorphic to the pattern graph.

A computer-readable storage medium storing a set of instructions, the set of instructions capable of being executed by a processor, the set of instructions performing the steps of generating a usage task from usage data, constructing a pattern graph from the usage task, constructing a model graph which represents a space of equivalents to the usage task represented by the pattern graph and extracting sub-graphs from the model graph, wherein each of the extracted sub-graphs is isomorphic to the pattern graph.

### BRIEF DESCRIPTION OF THE DRAWINGS

The accompanying drawings are included to provide a further understanding of the invention and are incorporated in and constitute part of the specification, illustrate several embodiments of the invention and, together with the description, serve to explain examples of the present invention. In the drawings:

FIG. 1 shows an action request system (“ARS”) to be subjected to a stress test according to the present invention;

FIG. 2 shows an exemplary task associated with a user session when interacting with the ARS application;

FIG. 3 shows an exemplary generalization method for creating multiple virtual tasks to be used with the stress test application according to the present invention;

FIG. 4 shows an exemplary block diagram representing the API calls for the exemplary real usage task of FIG. 2 according to the present invention;

FIG. 5 shows an exemplary DAG pattern graph for the query API calls shown in FIG. 4 according to the present invention;

FIG. 6 shows an exemplary model graph showing the available alternatives for the API calls in the DAG pattern graph of FIG. 5 according to the present invention;

FIG. 7a shows a first exemplary sub-graph of the model graph of FIG. 6 that is isomorphic to the pattern graph of FIG. 5 according to the present invention;

FIG. 7b shows a second exemplary sub-graph of the model graph of FIG. 6 that is isomorphic to the pattern graph of FIG. 5 according to the present invention;

FIG. 8 shows an exemplary method of constructing a pattern graph according to the present invention;

FIG. 9 shows an exemplary set of form data which is part of an application to be tested according to the present invention;

FIG. 10 shows the pattern graph representation of an operation according to the present invention;

FIG. 11 shows an exemplary model graph of valid alternatives to the pattern graph of FIG. 10 according to the present invention;

FIG. 12 shows one exemplary isomorphic sub-graph which may be extracted from the model graph of FIG. 11 according to the present invention;

FIGS. 13a-b shows a first exemplary breadth-first search method according to the present invention;

FIGS. 14a-b shows a second first exemplary depth-first search method according to the present invention.

### DETAILED DESCRIPTION

The present invention provides a method for performing a stress test on application software through the use of simulation techniques. The application software may be any piece of software that requires interaction with a user (e.g., databases, webserver, online game, CRM software, ERP software, etc.). The simulation technique creates virtual users that interact with the software application in the same manner as actual users. For the purposes of this description, the exemplary embodiment of the present invention will be referred to as the stress test application.

The stress test application described with reference to the present invention may run on a plurality of computer systems. Such computer systems may include memory that stores the code, a processor that runs the software, and various input and output means to allow a user to run the stress test. Furthermore, it should be understood that the terms software, program, code and application are used throughout this description to indicate software code that is run on a processor to accomplish a specific goal.

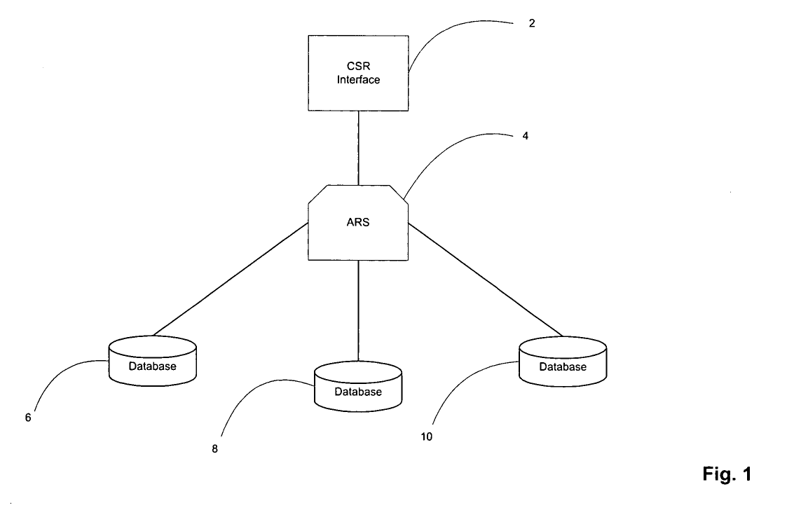

The exemplary embodiment of the stress test application of the present invention will be described in reference to a load test of an action request system application (“ARS application”) 4, which is software that may be used by customer support representatives (“CSR”) as shown in FIG. 1. The CSRs may be, for example, the staff at a call center. Thus, a CSR is an exemplary user of application software.

As shown in FIG. 1, the CSR interacts with the ARS application 4 via a CSR interface 2. The CSR interface 2 may include a plurality of software and hardware components that facilitate communication between the CSR and the ARS application 4. For example, the CSR interface 2 may include a device to accept input from the CSR (e.g., keyboard, mouse, touchpad, etc.) and a device to provide output to the CSR (e.g., monitor, printer, etc.). The ARS application 4 also has access to a plurality of databases 6-10, which may be of any type (e.g., SQL). The CSR may access the databases 6-10 via the CSR interface 2 and ARS application 4 to extract relevant information. For instance, if the CSR is communicating with a customer, the CSR may use the ARS application 4 to quickly view that customer's name, address, credit rating, and other information.

In a typical call center, there may be hundreds, or even thousands, of CSRs simultaneously accessing the ARS application 4 and associated databases 6-10 in order to service the customers. Thus, to accurately stress test an application (e.g., ARS application 4), the stress test application should simulate both the expected number of users along with their expected interactions with the application.

To simulate the typical user's interaction with the application, a record of user interactions with the application is required, such as application program interface (“API”) calls. Each API call is issued by the application in response to user actions (e.g., log in, search, manipulate data, etc.). According to the present invention, in order to simulate users for a stress test, API calls from a multitude of users are necessary. However, to avoid obtaining and/or creating API records for all actual users, which is very time consuming and inefficient, virtual user API records may be generated and used instead. Virtual user API records may be generated from at least one actual API record using a generalization method, as described in more detail below.

The actual API record may be obtained in a plurality of manners. For example, most applications generate a log file which contains the records of the API calls. As stated above, API calls may be any executable action requested by the user and performed by the application (e.g., searching the database, viewing data, logging in, terminating application, etc.). Thus, the application may keep a log of each of the API calls by the application during a session by a user. This log file allows the stress test application to capture real usage data from an actual user. It also has the benefit of allowing the capturing of this data long after the user has executed the tasks, i.e., the log file can be captured for as long as the application stores the log files in the memory (e.g., hard drive).

Another manner of obtaining a record of API calls (i.e., if a log file cannot be obtained) is to capture the API calls as a CSR is utilizing the ARS application 4. The API calls may be intercepted using a plurality of methods (e.g., disguising a record keeping file as an executable, etc.). In this manner, the stress test application monitors the flow of information between the ARS application and the user and the type of API calls made to facilitate this flow of information. Thus, the stress test application captures the API calls by the ARS application 4. Those of skill in the art will understand there may be numerous other manners of obtaining an actual API record based on an actual user's manipulation of application software.

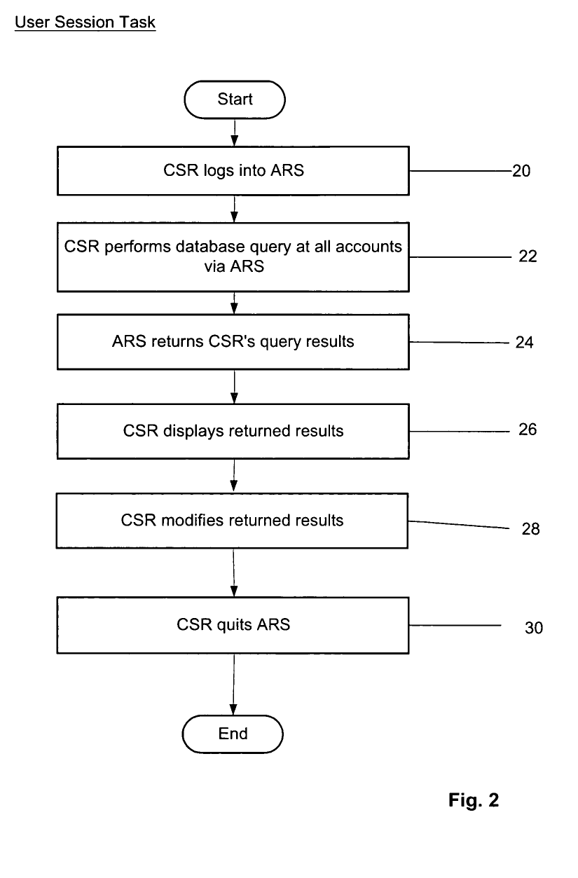

FIG. 2 shows an exemplary CSR user session when interacting with the ARS application 4. As described above, for each of the actions and requests made by the user, the ARS application executes one of more API calls to execute the requested action or request. In the exemplary user session, the CSR logs into the ARS application 4 in step 20. The CSR has to input a correct log-in name and password in order to obtain access to one or more databases that the ARS application 4 controls. After logging-in, the CSR may then perform a plurality of operations. In step 22, the CSR requests that the ARS application 4 perform a search of the ARS databases 6-10 based on a parameter or set of parameters entered by the CSR. For example, the CSR may request a search for all customer accounts which contain a specific name or phrase, are in a specified location, have a specified balance on the account, etc. In step 24, after ARS application 4 obtains the customer accounts that fit the CSR's query and provides the CSR with a list of those accounts. In step 26, the CSR views the generated results by displaying them using the CSR interface 2. In step 28, the CSR modifies parameters in the customer record (e.g., name, address, phone numbers, etc.). In step 30, after the user has finished with the current query session and the modification, the CSR terminates the ARS application 4.

Those of skill in the art will understand that the above user session was only exemplary and there are a limitless number of user session variations based on the particular software application. For example, in the above session, the CSR may revert to the start of the application (e.g., start a new search) at any point of the execution of the ARS application 4, the ARS application 4 may return multiple records for which an additional sub-search is performed, the user may continue to other operations before terminating the ARS application 4, etc. However, as described above, for each of the actions and requests by the user, the ARS application 4 performed one or more API calls to execute the action and/or request. This series of API calls may be termed a task or a usecase. Thus, the CSR's API record of the above actions represents an exemplary task that may be used to perform a stress test of the ARS application 4 as discussed in more detail below.

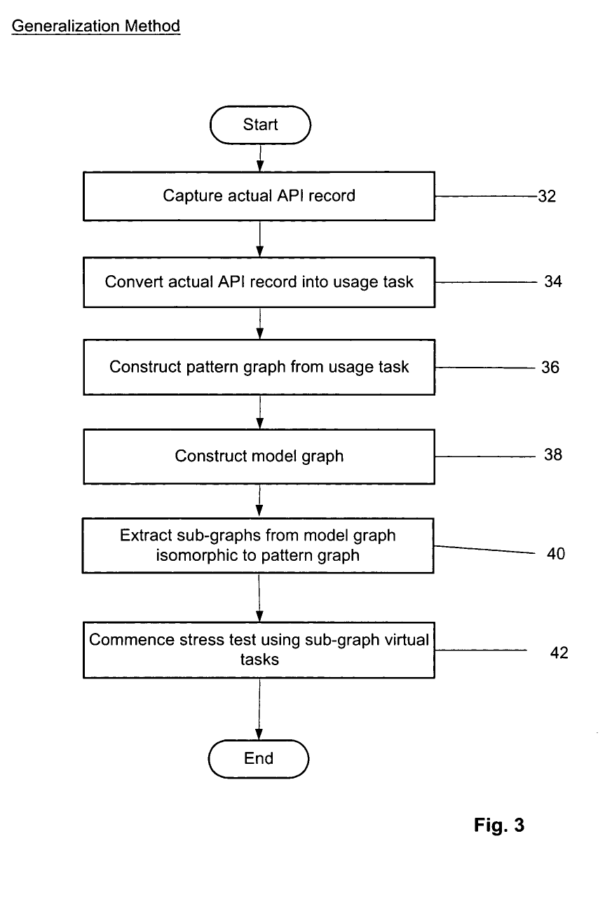

FIG. 3 shows an exemplary generalization method for creating multiple tasks to be used with the stress test application. In step 32, an actual API record is captured by the stress test application. For example, the API record associated with the task described above with reference to FIG. 2. This API record may be obtained using the methods described above, e.g., by accessing a log file of the ARS application 4, etc. In step 34, after the actual API record is obtained, it is parsed from a log file or another source and is then converted into a task via the generalization method which parses the API calls from the log file or other source (i.e., API record described above) and generates a task. The goal of the generalization method is to take an individual task based on real usage data and generate multiple virtual tasks that simulate multiple users or multiple tasks performed by a single user. Each of the tasks that are ultimately generated for the stress test application should be executable tasks.

For example, a developer using the stress test application may determine that in a typical use pattern the ARS application 4 may have one hundred (100) simultaneous users and therefore, the stress test application should have one hundred (100) virtual users to run the stress test. The stress test application could take the original real usage data task described above and have multiple virtual users perform this same task for the purposes of the stress test. However, this is not a realistic test for the ARS application 4, because it is highly unlikely that each of the one hundred simultaneous users would be performing the exact same task. Thus, the purpose of the generalization method is to have the one hundred virtual users perform similar, but not identical, tasks based on the captured real usage data. The generalization will happen within the constraints set by the captured task, but the virtual tasks will not be identical to the captured task.

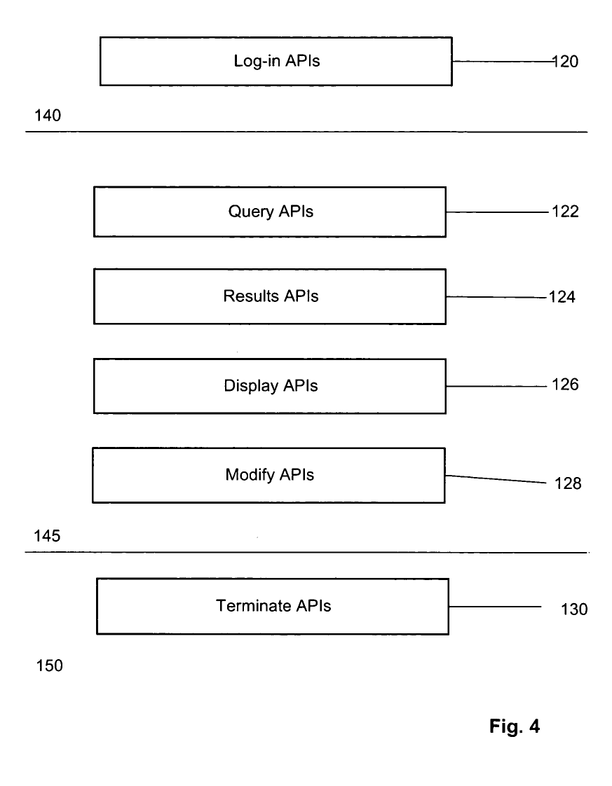

In creating tasks, the generalization method may separate the captured tasks into individual blocks based on the functionality of the API calls. For example, FIG. 4 shows blocks representing the API calls for the exemplary real usage task of FIG. 2. Thus, the log-in API calls 120 are the API calls associated with the CSR logging into the ARS application 4 as shown in step 20 of FIG. 2. Similarly, the query API calls 122 are associated with the search step 22, the results API calls 124 are associated with the return step 24, the display API calls 126 are associated with the display step 26, the modify API calls 128 are associated with the modification step 28 and the terminate API calls 130 are associated with the quit step 30. As described above, for each of the steps 20-30 of FIG. 2, there may be one or more API calls by the ARS application 4 to complete the steps.

FIG. 4 shows that the API calls 120-130 are broken into separate blocks according to the functionality of the API calls. In this example, the log-in API calls 120 are in a first block 140, the API calls 122-128 are in a second block 145 and the terminate API calls 130 are in a third block 150. This separation of API calls into different blocks 140, 145 and 150 represents the functionality associated with each of the API calls in the blocks for the purpose of generating the virtual tasks. For example, each of the virtual users must log-in to the ARS application 4. Thus, the log-in API calls 120 are the same for each of the virtual tasks and will not be altered, meaning that each virtual task will include the same log-in API calls 120. Similarly, each of the virtual users will terminate the ARS application 4. Thus, the terminate API calls 130 are the same for each of the virtual tasks and will not be altered from the real usage task.

In contrast, the API calls 122-128 associated with the second block 145 may be considered the work portion of the task, i.e., where the user selected a specific sequence of functions for the ARS application 4 to perform. Thus, the user may have chosen an alternate course of action in this work portion 145 of the task. These alternate courses of action may be the set of virtual tasks that the generalization method may create for the virtual users. The generalization method according to an exemplary embodiment of the present invention allows the API calls 122-128 in the second block 145 to be replaced with equivalent API calls. These replacement API calls may change parameters within the API calls (e.g., changing a search string used for the query API calls 122) or change the API calls themselves (e.g., changing the display API calls 126 to print API calls). By making these changes, the generalization method creates the virtual tasks to be used by the stress test application.

However, the generalization method must replace the API calls 122-128 without violating any dependencies within the sequence of API calls. According to the exemplary embodiment of the present invention, the generalization method uses a system of graphs to construct the virtual API tasks. There are various types of graphs which may be used to construct the virtual API tasks such as directed tree graphs and directed acyclic graphs (“DAG”). DAG is a preferred graph data structure because the nodes of a DAG may be linked in an efficient manner.

In step 36, the generalization method translates the real usage task (i.e., the actual API record) into a pattern graph. The generalization method forms the pattern graph from the task by first identifying a set of generalizable entities, i.e., those entities that may be altered such as the API calls in the block 145 of FIG. 4. The pattern graph represents a formal description of the generalizable entities and their relationship in a given task. Generalizable entities have an entity template associated with them that will be varied in the course of generalization. An API call to log-in (block 140) or terminate (block 150) by the CSR is not a generalizable entity since it cannot be varied. Therefore, the pattern graph only shows those API calls that are generalizable as nodes.

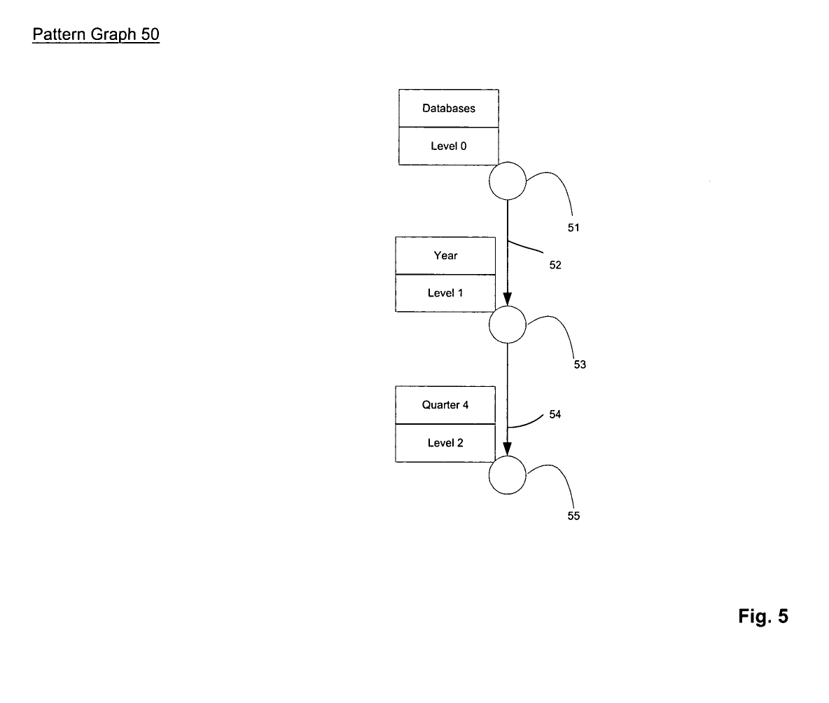

FIG. 5 shows an exemplary DAG pattern graph 50 for the query API calls 122 shown in FIG. 4. In this example, it should be considered that in step 22 of FIG. 2, the CSR requested that the ARS application 4 perform a query of the databases 6-10 for records associated with the fourth quarter of a particular year. Thus, the query API calls 122 shown in FIG. 4 included the parameter “year” and “quarter 4” for the search to be performed.

For each one of the generalizable entities the generalization method creates and assigns a fully-qualified name. A fully-qualified name entity consists of a set of local entity names connected by associative qualifiers. For example, “Databases.Year.Quarter4” is a fully-qualified entity name where “Databases,” “Year,” and “Quarter4” are local entity names and the “.” are the associative qualifiers. “Databases.Year.Quarter4,” for example, represents an API call by the CSR in step 22 where the CSR searched for records associated with the fourth quarter of a particular year as described above.

The pattern graph 50 generated for the API calls 122 includes data nodes 51, 53 and 55 and edges 52 and 54. The pattern graph 50 is a data structure that contains information about the API calls. Each node includes a node value and a node property. In node 53, the node value is “year” and the node property is “level 1”. The fully-qualified name described above is broken into the nodes 51, 53 and 55 with each local name stored as the node value. The node value may store any information regarding the API call such as the user-issued command or the property of the user's command. Thus, the node value for node 51 shows that the databases should be queried, the node value for node 53 shows that the first query level should be a particular year and the node value for the node 55 shows that the fourth quarter of the particular year should be queried.

In this example, the node property references the particular node's position within the graph (e.g., node 51 is at Level 0, node 53 is at Level 1 and node 55 is at Level 2), i.e., the node properties are related to the level of search parameter within the databases 6, 8 and 10 of the ARS application 4. However, there may be other methods of labeling the dimensional properties of the nodes. For example, a display node may always be before a print node, thus, the display node and the print node may have their dimensional properties named in such a manner to indicate this dependency. It should also be noted that the node properties are not limited to dimensional properties and that another manner of identifying the node properties may be through the use of a node label. The node label may be considered the set of node properties for a particular node. Thus, for the node 53, the node label may contain the set of node properties for the node 53. In this example, the set of node properties only includes the level node property described above, but it may include any number of other properties. Similarly, the set of properties may be null, resulting in an unlabelled node.

The properties that may be used for the nodes may depend on the application for which the generalization is being applied. The properties will qualify all the characteristics of a generalizable entity that have to be equal to the properties of an alternative entity, in order to make those entities isomorphic. Some examples of properties include an OPERATOR which states that the entity appears as an operator in the context of an SQL statement, a UNIQUE_ID which signals that the entity represents a unique id in the context of a database table, an INTEGER which indicates the entity is an integer, a UNICODE_CHARACTER which indicates the entity satisfies the requirements of a unicode character, a BASIC_LATIN_CHARACTER which indicates the entity satisfies the requirements of a basic Latin character set of the unicode character, etc. The above are only exemplary and there may be many other properties based on the particular application.

The associative qualifiers are the elements that connect local entity names in a fully qualified name. An associative qualifier will be represented as an edge when the a fully qualified name is turned into a graph representation. Each local name may also be a fully or partially qualified name by itself, which can have the same pattern of local names and qualifiers. Thus, entities with identical fully-qualified names are considered equivalent.

An edge is related to a node and is directed which reflects the ordering of the nodes. Thus, edge 52 is related to node 51 and edge 54 is related to node 53. The directional nature of the edges 52 and 54 reflects that the API call for node 51 must precede the API call for node 53. In this example, the edges 52 and 54 do not carry any labels. However, the edges may be also be labeled in a manner similar to the nodes 51, 53 and 55.

The pattern graph is created by starting with the first local names of all fully-qualified names, where each name is represented as a node with the assigned properties as the node's property set. Identical names with the same set of properties are represented by the same node. The starting node only has outgoing edges and is thus the root of the hierarchy. The pattern graph construction is a recursive process that starts with the root node. A child node of the root node is obtained for each child entity with a distinct set of properties. Thus, the root node in the exemplary embodiment is “databases” node 51 while its child node is “databases.year” node 53 and, in turn, node 53 has child node “databases.year.quarter4” node 55.

At the completion of step 36 the generalization method has created a pattern graph which represents the API calls for the real usage data captured from an actual user. Those of skill in the art will understand that the pattern graph 50 of FIG. 5 is not the entire pattern graph for the exemplary real usage data of FIG. 2 and API calls of FIG. 4. The pattern graph 50 is only for illustrative purposes and therefore only represents the pattern graph for the query API calls 122 of FIG. 4.

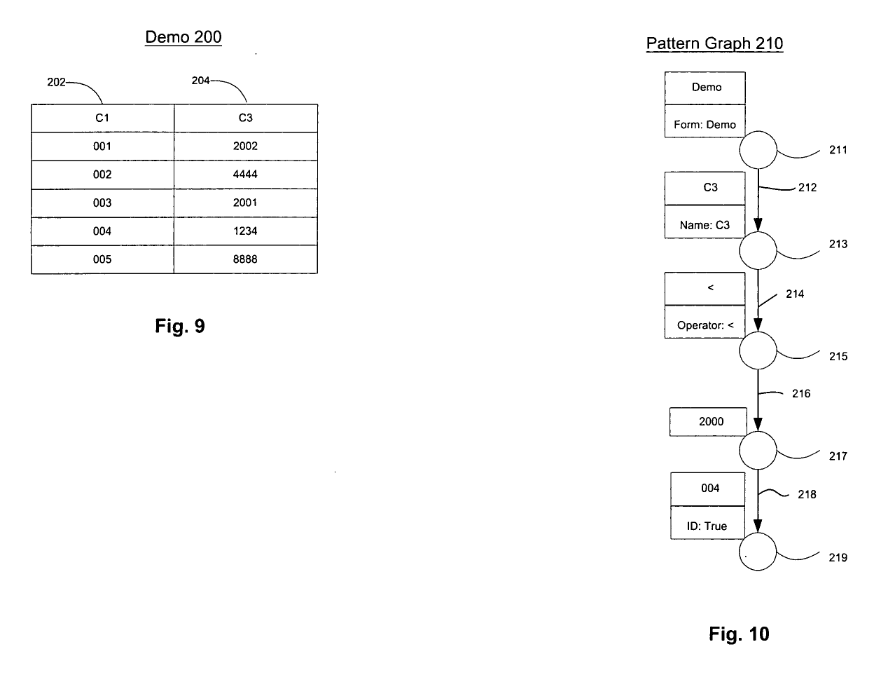

FIG. 8 shows an exemplary method 90 of constructing a pattern graph which is a summary of the above description. In step 92, the set of generalizable entities within a given task is identified. Thus, for a task T, the set E_{T} of generalizable entities is identified. The set E_{T} includes the generalizable entities e₁, e₂, e₃, . . . e_{N}. In step 94, the fully qualified names of each of the generalizable entities e₁, e₂, e₃, . . . e_{N} are identified. In step 96, a label (set of properties) is assigned to each of the generalizable entities e₁, e₂, e₃, . . . e_{N} or the connectors (or associative qualifiers), (e.g., the edges). Default properties for the entities and the connectors may be depth and direction, respectively.

Finally in step 98, the pattern graph may be constructed by merging the set of fully qualified names into a graph. In the graph, each fully qualified name for an entity is represented as a node with the properties being assigned as the node label. Identical names with the same set of properties are represented by the same node. Similarly, each connector with its property (e.g., direction) maps onto the edges which connect the nodes. A result of this exemplary method of merging the set of fully qualified names is that the pattern graph is guaranteed to be a DAG. Those of skill in the art will understand that it is possible to construct pattern graphs of different types.

In order to generate virtual tasks, the generalization method creates a model graph in step 38 as shown in FIG. 3. The model graph represents the space of all the alternatives available to the user, i.e., equivalent paths to the path actually taken by the user. Since the model graph represents the available alternatives, it essentially represents the application itself or the application module for which generalization should be applied. The generalization method generates a model graph by creating a single starting node using a recursive process similar to the construction of the pattern graph as shown in FIG. 5. However, the model graph may contain more nodes which represent a larger set of possible API calls and their properties than the pattern graph.

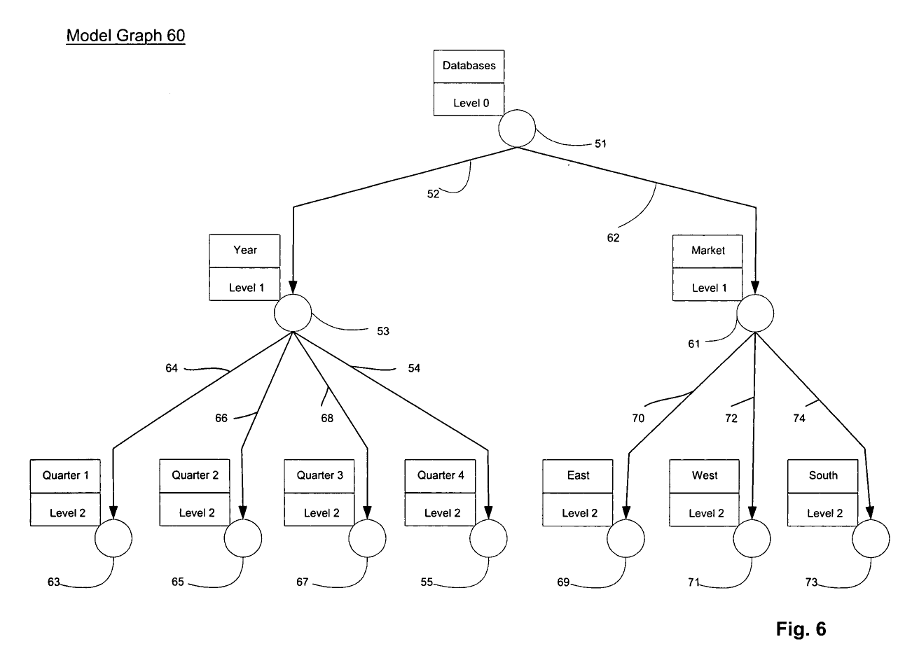

FIG. 6 shows an exemplary model graph 60 showing the available alternatives for the API calls in the DAG pattern graph of FIG. 5. The model graph 60 shows the nodes and edges from the pattern graph 50, i.e., node 51 (databases) with edge 52 pointing to node 53 (year) with edge 54 pointing to node 55 (quarter 4). However, it also shows equivalent alternatives to the original API calls. For example, node 51 (databases) has a second edge 62 leading to node 61 (market) which is equivalent to the original API call associated with node 53 (year). Thus, in this example, the user of ARS application 4 could have searched the databases 6, 8 and 10 for accounts based on the market (node 61) rather than by year (node 53).

The model graph must retain all the dependencies between the original API calls so that when the virtual API calls are extracted from the model graph, the ARS application 4 can handle the virtual API calls. Thus, each of the edges leading from the node 53 (year) to the level 2 nodes 63,65, and 67, i.e., edge 64 leading to node 63 (quarter 1), edge 66 leading to node 65 (quarter 2) and edge 68 leading to node 67 (quarter 3), are equivalent to the original API call associated with edge 54 and node 55 (quarter 4). Similarly, each of the edges leading from node 61 (market) to the level 2 nodes 69, 71 and 73, i.e., edge 70 leading to node 69 (east), edge 72 leading to node 71 (west) and edge 74 leading to node 73 (south) are also equivalent to the original API call associated with edge 54 and node 55 (quarter 4). The equivalence is based on the dependencies from the original API calls. For example, a virtual API call may contain a search for the year (node 53) and a different quarter, e.g., quarter 1 (node 63 and edge 64). However, a virtual API call may not contain a search for the year (node 53) and a different region, e.g., east (node 69 and edge 70) because that would violate the dependencies between the original API calls. Those of skill in the art will understand that in the present example the dependencies are based upon the searching pattern for the data in the databases 6, 8 and 10. There may be other manners of determining dependencies within the APIs such as reviewing the published APIs for the application to determine dependencies.

As shown in model graph 60, the node 51 (databases) is a root node which, in this example, does not have any equivalents. This means that a user attempting to perform a search using the ARS application 4 does not have any alternatives to search other than the databases 6, 8, and 10.

The recursive process to construct the model graph starts by identifying the root node which is the top of the hierarchy. In the naming scheme described above, the root node will have a fully qualified name that is identical to the entity name. In the example of model graph 60, the root node 51 has the fully qualified name “databases” which is the same as the entity name of “databases”. Thus, the node 51 is the root node in this example. The process then continues such that for each child of the root node with a distinct set of properties, child entities which match those properties are obtained resulting in the model graph 60. It should be noted that it may be possible that two or more nodes may contain the same node value. In such a case, the node properties of the different nodes are different, but the values may be the same.

Furthermore, it is possible that a single generalizable entity may map onto multiple nodes. For example, if a search term such as “net” is a generalizable entity, the search term may be expressed as multiple nodes, e.g., a first node having the value “n”, a second node having a value “e”, and a third node having a value “t”. Such a method of assigning multiple nodes to a generalizable entity allows for a greater number of potential alternatives because there may be an alternative for each of the nodes.

The generalization method then extracts sub-graphs from the model graph 60 which are isomorphic to the original real usage data pattern graph 50 as shown in step 40 of the generalization method. A sub-graph of the model graph 60 is isomorphic to the pattern graph 50 if the sub-graph's nodes, node properties and the direction of the edges are identical termed sub-graph isomorphism (“SGI”). The resulting sub-graphs are the virtual tasks that will be used for the stress test.

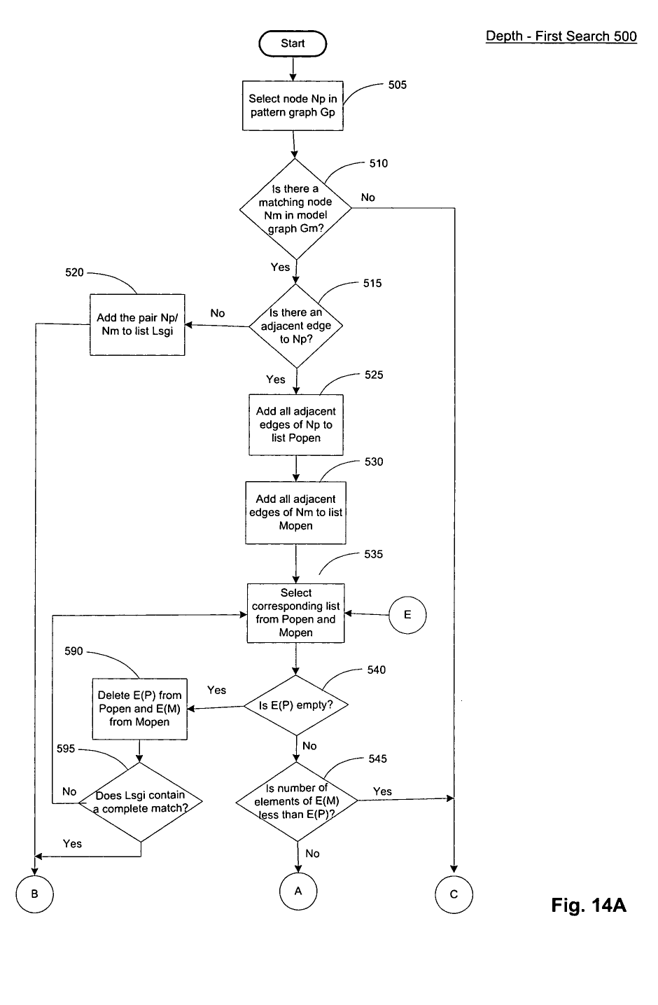

The following describes two exemplary methods for searching the model graph to find isomorphic subgraphs. FIGS. 13a-b show the first exemplary breadth-first search method 300. The method assumes that there is a pattern graph G_{P} with k nodes and i edges, where each edge connects two nodes that are in G_{P}. In addition, there is a model graph G_{M} with r nodes and t edges where each edge connects two nodes that are in G_{M}. The method will be described with reference to pattern graph 50 of FIG. 5 and model graph 60 of FIG. 6.

The method begins in step 305 by selecting a node n_{P} in pattern graph G_{P} according to a specified selection mechanism. The specified selection mechanism may be extensible and may be based on any arbitrary constraint, including a random selection. In this example, it may be assumed that the first node selected is the root node or node 51 of pattern graph 50. The method may start by selecting any node and the selection of node 51 is only exemplary.

The method then continues to step 310 to determine if there is a matching node n_{M} in model graph G_{M}. The matching node may be determined using the node properties of the selected node n_{P} and the various nodes of the model graph. If there is no matching node n_{M}, the method is finished because there can be no isomorphism if there are no matching nodes n_{M} in the model graph G_{M}. In this example, there is a matching node in the model graph 60, i.e., node 51 (the same node). Thus, the method continues to step 315 to determine if there are any adjacent edges to the selected node n_{P} of the pattern graph G_{P}. If there are no adjacent edges, the method continues to step 320 where the matching pair n_{P}/n_{M} are added to a list L_{SGI}.

The step 320 is a generally unique case where a pattern graph has a single node and the model graph has equivalent nodes, but there are no edges adjacent to the selected node n_{P}, meaning that each of the matching nodes n_{M} in the model graph G_{M} are isomorphic to the pattern graph. Thus, the method is successful, because each of the matching pairs n_{P}/n_{M} added to a list L_{SGI} are iso-morphic subgraphs of the pattern graph G_{P}.

The more normal case, as in this example, is that there are adjacent edges in the pattern graph to the selected node n_{P}. The method then continues to step 325 where all adjacent edges of n_{P} are added to a list P_{OPEN}. Referring to FIG. 5, the selected node 51 has a first adjacent edge 52 which connects node 51 and node 53. Thus, this set of information is stored in the list P_{OPEN}, i.e., node 51/edge 52/node 53. In the present example, the edge 52 is the only adjacent edge to the node 51. Thus, at the end of step 325, the list P_{OPEN} will contain one set of data, node 51/edge 52/node 53. The sets of data stored in P_{OPEN} and later in M_{OPEN} may be referred to as elements.

The method continues to step 330 where all the adjacent edges to the matching node n_{M} in the model graph G_{M} are added to a list M_{OPEN} in a similar manner as described for the list P_{OPEN} in step 325. Thus, in the present example, the method would add the information for the adjacent edges to node 51 of the model graph 60 to the list M_{OPEN}, e.g., node 51/edge 52/node 53 and node 51/edge 62/node 61.

The method then continues to step 335 where a search depth parameter is set to a first level meaning that the method will first attempt to find isomorphisms between the first level adjacent edges of the pattern graph G_{P} and the first level adjacent edges of the model graph G_{M}, e.g., a search depth parameter d may be set to 0. In step 335, the method also selects the first set of information E(P) and E(M) from the list P_{OPEN} and M_{OPEN}, respectively. Thus, in the example, the method would select the sets of information from the first level of P_{OPEN}, i.e., E(P)=node 51/edge 52/node 53, and the first sets of information from the first level of M_{OPEN}, i.e., E(M)=node 51/edge 52/node 53 and node 51/edge 62/node 61. Thus, E(P) has one element e_{P1} and E(M) has two elements e_{M1} and e_{M2}.

The method then continues to step 340 to determine whether the list E(P) is empty. This step is generally not relevant when the first list is selected because it has already been determined above in step 315 that at least one adjacent edge exists and thus, for the first list, the E(P) will not be empty. However, as the method is iterated, this step becomes important in determining whether additional matches need to be found. At this point, the description will continue as if the E(P) is not empty as in the current example where E(P) includes element e_{P1}. The description of the subsequent steps to be performed if E(P) were empty will be described below.

The method continues to step 345 where it is determined if the number of elements in E(M) is less than the number of elements in E(P). If the number of elements in E(M) is less than the number of elements in E(P), the method is stopped because there cannot be an isomorphism found for this data. If the number of elements in E(M) is greater than or equal to the number of elements in E(P) (as in the present example, two elements in E(M) and one element in E(P)), the method continues to step 350, where the next element of E(P) is selected for further processing.

In this example, the next element is the first element e_{P1} of E(P). The method continues to step 355 where it is determined if E(M) has any remaining elements to be matched. Again, in the first iteration, this step will be answered in the positive. However, in further iterations, it may be answered in the negative, when, and if, the complete set of elements in E(M) has been tested for a match to an element of E(P) and no elements in E(M) are a match. If this were the case, the method would end because if there is not a match for all the elements of E(P), there will be no sub-graph isomorphisms in the model graph.

In the present example, there are elements in E(M) that have yet to be tested, i.e., e_{M1} and e_{M2}. The method therefore continues to step 360 where the next element is selected from E(M) to be checked for a match. In this example, the next element is e_{M1}. The process continues to step 365 where it is determined whether the current element e_{M} matches the current element e_{P}. If the current elements e_{M} and e_{P}, do not match the method loops back to step 355 where it is determined if there are any elements left in E(M) to which element e_{P} may be compared for a match. If there are no elements left, the process ends, if there is an element remaining, the method continues to step 360 for the next element e_{M} to be selected for comparison in step 365.

In the present example, the first iteration of step 365 would yield a match, i.e., element e_{M1} (node 51/edge 52/node 53) matches element e_{P1} (node 51/edge 52/node 53). As described above for the matching of the nodes, a match may be determined by comparing the properties of the nodes and edges contained in each element. The elements e_{P1} and e_{M1} match because the properties associated with the nodes and edges in e_{P1} and e_{M1} are equivalent, and in this example, identical. In a further example, the first element of E(M) that was checked may have been e_{M2} (node 51/edge 62/node 61). In this example, e_{P1} includes information on the set of node 51/edge 52/node 53, while and e_{M2} includes information on the set of node 51/edge 62/node 61. This may also be a match based on the properties of the nodes and edges in each element.

If the current elements e_{M} and e_{P} do match in step 365, the method continues to step 370 where the matching pair is stored in the list L_{SGI}. Thus, in the present example the matching pair e_{P1}/e_{M1} may be stored in the list L_{SGI}. The matching pairs are stored in the list L_{SGI} with an indication of the search level on which the pair was matched, e.g., d=0, so that there is a depth indication for each of the pairs. It should be noted that it is possible to create parallel search threads for the various elements in E(P). Thus, the search for matches for multiple elements in E(P) may be performed simultaneously using different search threads.

The method then continues to step 375 where the matched elements are removed from E(M) and E(P). Thus, in this example, e_{P1} is removed from E(P) and e_{M1} is removed from E(M). The method then loops back to step 340 to determine if E(P) is empty. If E(P) is not empty, the process continues to steps 345-375 as described above for the next element e_{P} in E(P).

In the present example, in step 340, the list E(P) is empty because the single entry e_{P1} has been removed in step 375. Thus, when step 340 is carried out, E(P) will be empty and the method would proceed to step 380 where E(P) is deleted from the list P_{OPEN} and E(M) is deleted from the list M_{OPEN}, leaving P_{OPEN} and M_{OPEN} empty. The process then continues to step 385 where it is determined if the list L_{SGI} contains a complete match for all the elements for the pattern graph G_{P}. If the list L_{SGI} contains a complete match for all the elements for the pattern graph G_{P}, then a sub-graph isomorphism has been found for the pattern graph G_{P} and the method is complete. However, if the list L_{SGI} does not contain a complete match for all the elements for the pattern graph G_{P}, then additional checking needs to be performed.

In the present example, the list L_{SGI} will not contain a complete match because the edge 54 and node 55 have not been addressed up to this point. Therefore, the method continues to step 390 to where the last list added to the list L_{SGI} is set to L₀. Thus, in the present example, the last list added to L_{SGI} is the matching pair e_{P1}/e_{M1}. The method then continues to step 395 where all adjacent edges to L₀ are added to P_{OPEN} In this example, the adjacent edges to e_{P1} in L₀ is the edge 54 which connects the nodes 53 and 55. Thus, the element node 53/edge 54/node 55 will be added to the list P_{OPEN}.

Similarly, the method then continues to step 400 where all adjacent edges to L₀ are added to M_{OPEN}. In this example, the adjacent edges to e_{M1} in L₀ are the edges 64, 66, 68 and 54. Thus, the elements node 53/edge 64/node 63, node 53/edge 66/node 65, node 53/edge 68/node 67, and node 53/edge 54/node 55 would be added to the list M_{OPEN}.

The process then loops back to step 335 where the search depth level is set to the next level, e.g., the second level (d=1), and the elements in P_{OPEN} are set to E(P) and the elements in M_{OPEN} are set to E(M) and the method continues as described above. As should be apparent from the present description, the method will iterate through the number of search levels present in the pattern graph until a sub-graph isomorphism is found (step 405) or until the method fails because there is no sub-graph isomorphism.

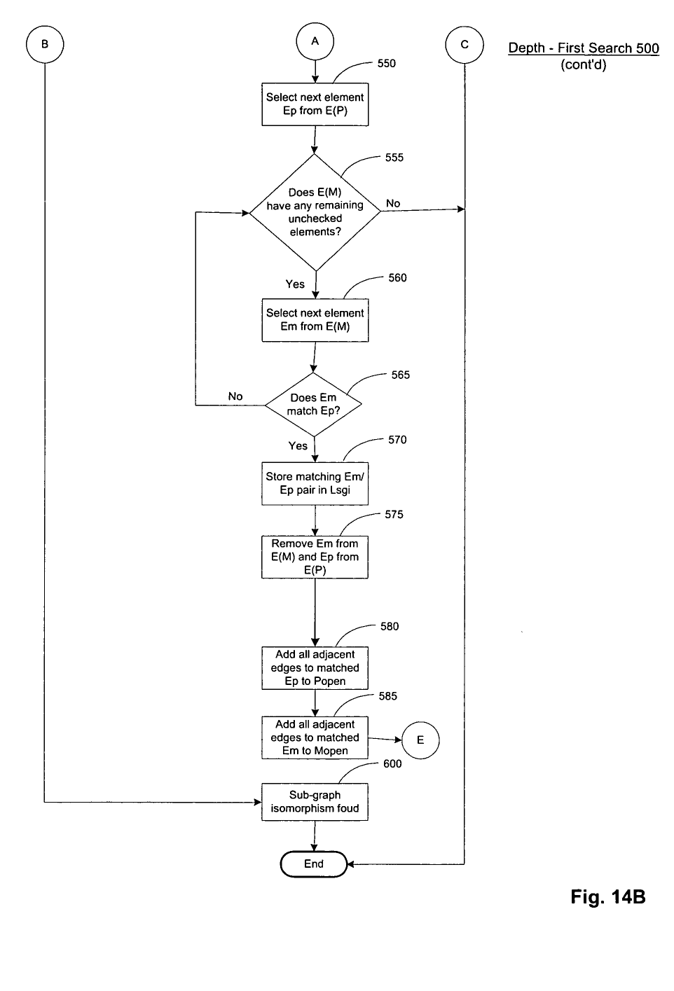

FIGS. 14a-b show a second first exemplary depth-first search method 500. Similar, the breadth-first method 300, the method 500 assumes that there is a pattern graph G_{P} with k nodes and i edges, where each edge connects two nodes that are in G_{P}. In addition, there is a model graph G_{M} with r nodes and t edges where each edge connects two nodes that are in G_{M}. The method 500 will also be described with reference to pattern graph 50 of FIG. 5 and model graph 60 of FIG. 6.

The steps 505-530 in the method 500 are the same as the steps 305-330, respectively, in the method 300. Thus, these steps will not be described for a second time. In step 535, the method also selects the first set of information E(P) and E(M) from the list P_{OPEN} and M_{OPEN}, respectively. Thus, in the example, the method would select the sets of information from the first level of P_{OPEN}, i.e., E(P)=node 51/edge 52/node 53, and the first sets of information from the first level of M_{OPEN}, i.e., E(M)=node 51/edge 52/node 53 and node 51/edge 62/node 61. Thus, E(P) has one element e_{P1} and E(M) has two elements e_{M1} and e_{M2}.

The method then continues to step 540 to determine whether the list E(P) is empty. This step is generally not relevant when the first list is selected because it has already been determined above in step 515 that at least one adjacent edge exists and thus, for the first list, the E(P) will not be empty. However, as the method is iterated, this step becomes important in determining whether additional matches need to be found. At this point, the description will continue as if the E(P) is not empty as in the current example where E(P) includes element e_{P1}. The description of the subsequent steps to be performed if E(P) were empty will be described below.

The method continues to step 545 where it is determined if the number of elements in E(M) is less than the number of elements in E(P). If the number of elements in E(M) is less than the number of elements in E(P), the method is stopped because there cannot be an isomorphism found for this data. If the number of elements in E(M) is greater than or equal to the number of elements in E(P) (as in the present example, two elements in E(M) and one element in E(P)), the method continues to step 550, where the next element of E(P) is selected for further processing.

In this example, the next element is the first element e_{P1} of E(P). The method continues to step 555 where it is determined if E(M) has any remaining elements to be matched. Again, in the first iteration, this step will be answered in the positive. However, in further iterations, it may be answered in the negative, when, and if, the complete set of elements in E(M) has been tested for a match to an element of E(P) and no elements in E(M) are a match. If this were the case, the method would end because if there is not a match for all the elements of E(P), there will be no sub-graph isomorphisms in the model graph.

In the present example, there are elements in E(M) that have yet to be tested, i.e., e_{M1} and e_{M2}. The method therefore continues to step 560 where the next element is selected from E(M) to be checked for a match. In this example, the next element is e_{M1}. The process continues to step 565 where it is determined whether the current element e_{M} matches the current element e_{P}. If the current elements e_{M} and e_{P}, do not match the method loops back to step 555 where it is determined if there are any elements left in E(M) to which element e_{P} may be compared for a match. If there are no elements left, the process ends, if there is an element remaining, the method continues to step 560 for the next element e_{M} to be selected for comparison in step 565. In the present example, the first iteration of step 565 would yield a match, i.e., element e_{M1} (node 51/edge 52/node 53) matches element e_{P1} (node 51/edge 52/node 53).

If the current elements e_{M} and e_{P} do match in step 565, the method continues to step 570 where the matching pair is stored in the list L_{SGI}. Thus, in the present example the matching pair e_{P1}/e_{M1} may be stored in the list L_{SGI}. Once again, it should be noted that it is possible to create parallel search threads for the various elements in E(P). Thus, the search for matches for multiple elements in E(P) may be performed simultaneously using different search threads.

The method then continues to step 575 where the matched elements are removed from E(M) and E(P). Thus, in this example, e_{P1} is removed from E(P) and e_{M1} is removed from E(M). The method then continues to step 580 where all adjacent edges to the matched element e_{P1} are added to the beginning of the list P_{OPEN}. In this example, the adjacent edges to the matched element e_{P1} is the edge 54 which connects the nodes 53 and 55. Thus, the element node 53/edge 54/node 55 will be added to the beginning of the list P_{OPEN}.

Similarly, the method then continues to step 585 where all adjacent edges to the matched element e_{M1} are added to the beginning of the list M_{OPEN}. In this example, the adjacent edges to the matched element e_{M1} are the edges 64, 66, 68 and 54. Thus, the elements node 53/edge 64/node 63, node 53/edge 66/node 65, node 53/edge 68/node 67, and node 53/edge 54/node 55 would be added to the list M_{OPEN}.

The process then loops back to step 535 where the new elements added to P_{OPEN} in step 580 are set to E(P) and the new elements added to M_{OPEN} in step 585 are set to E(M) and the method continues as described above. When an iteration is reached where the E(P) is determined to be empty in step 540, the method continues to step 590 where E(P) is deleted from the list P_{OPEN} and E(M) is deleted from the list M_{OPEN}. The process then continues to step 595 where it is determined if the list L_{SGI} contains a complete match for all the elements for the pattern graph G_{P}. If the list L_{SGI} contains a complete match for all the elements for the pattern graph G_{P}, then a sub-graph isomorphism has been found for the pattern graph G_{P} and the method is complete.

However, if the list L_{SGI} does not contain a complete match for all the elements for the pattern graph G_{P}, then additional checking needs to be performed. The method loops back to step 535 where the elements remaining in the list P_{OPEN} are set to E(P) and the elements remaining in M_{OPEN} are set to E(M) and the method continues as described above.

As in the description of the method 300, the method 500 will iterate through the pattern graph until a sub-graph isomorphism is found (step 600) or until the method fails because there is no sub-graph isomorphism.

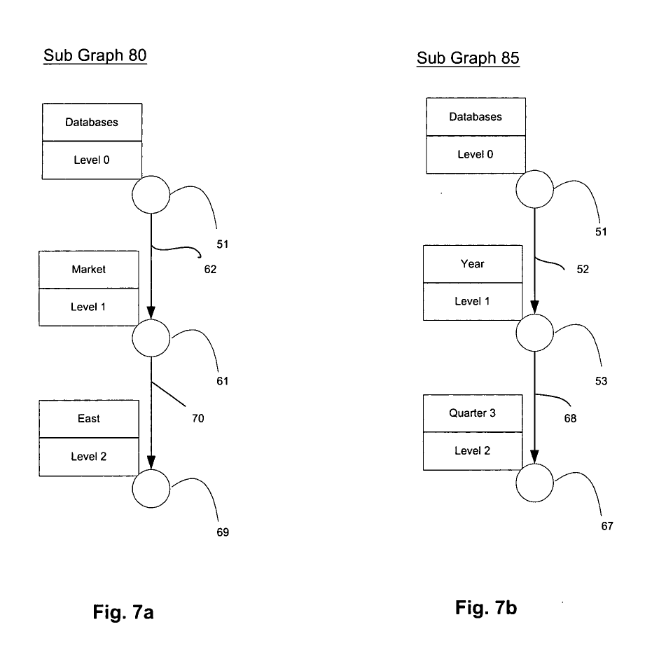

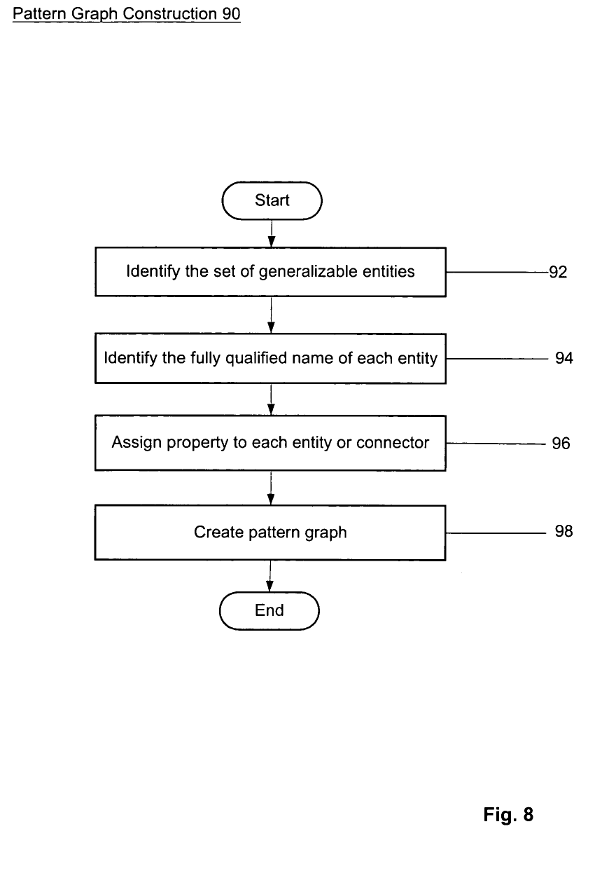

FIGS. 7a and 7b show two exemplary sub-graphs 80 and 85 of the model graph 60 that are isomorphic to the pattern graph 50. The sub-graph 80 is isomorphic to the pattern graph 50 because the properties of the nodes 51 (Level 0), 61 (Level 1) and 69 (Level 2) and the direction of the edges 62 and 70 of the sub-graph 80 are identical to the properties of the nodes 51 (Level 0), 53 (Level 1) and 55 (Level 2) and the direction of the edges 52 and 54 of the pattern graph 50. Similarly, the sub-graph 85 is isomorphic to the pattern graph 50 because the properties of the nodes 51 (Level 0), 53 (Level 1) and 67 (Level 2) and the direction of the edges 52 and 68 of the sub-graph 85 are identical to the properties of the nodes 51 (Level 0), 53 (Level 1) and 55 (Level 2) and the direction of the edges 52 and 54 of the pattern graph 50.

Since a sub-graph of a model graph is isomorphic to the pattern graph, then that sub-graph is a valid generalization of a the pattern graph and as a result it represents a variation of the original task. As described above, an isomorphic sub-graph is a valid variation of the original task because it maintains the properties and dependencies in the pattern graph which represents the original task. Thus, each of the isomorphic sub-graphs that are extracted from the model graph 60 are variations of the original user session task of FIG. 2, meaning that each of the extracted sub-graphs represents a virtual task that may be used by the stress test application to perform the stress test on the ARS application 4. Those of skill in the art will understand that the sub-graphs 80 and 85 are only exemplary and that there are multiple other sub-graphs which may be extracted from the model graph 60 that are isomorphs of the pattern graph 50.

In step 42 of the generalization method, after extracting sub-graphs, which represent the virtual tasks for use in the stress test, the stress test may commence. As described above, each of the SGIs that are extracted from the model graph represents a virtual task that is equivalent to the original usage task captured by the generalization method. If it were considered that there were one hundred (100) SGIs extracted from the model graph, then each of the one hundred (100) virtual users (as described in the original example) could simultaneously perform a unique virtual task during the stress test of the ARS application 4.

Those of skill in the art will understand that an actual stress test may test the application in numerous manners where it is not necessary to have a one-to-one correspondence between the number of virtual users and the number of virtual tasks. The correspondence may be greater or lesser than one-to-one. In addition, the actual stress test application may vary multiple parameters to perform the stress test such as the timing and number of virtual users task performance, the grouping of virtual user task performance, the timing and number of virtual user log-ins and terminations, etc.

Those of skill in the art will understand that the above example of the generalization method used the example of searching databases. However, any set of API calls performed by an application program may be generalized using the methods described above. In any case, the pattern graphs and model graphs are to be set up in such a way that the graphs maintain the dependencies and the properties of each of the generalizable entities within the set of API calls.

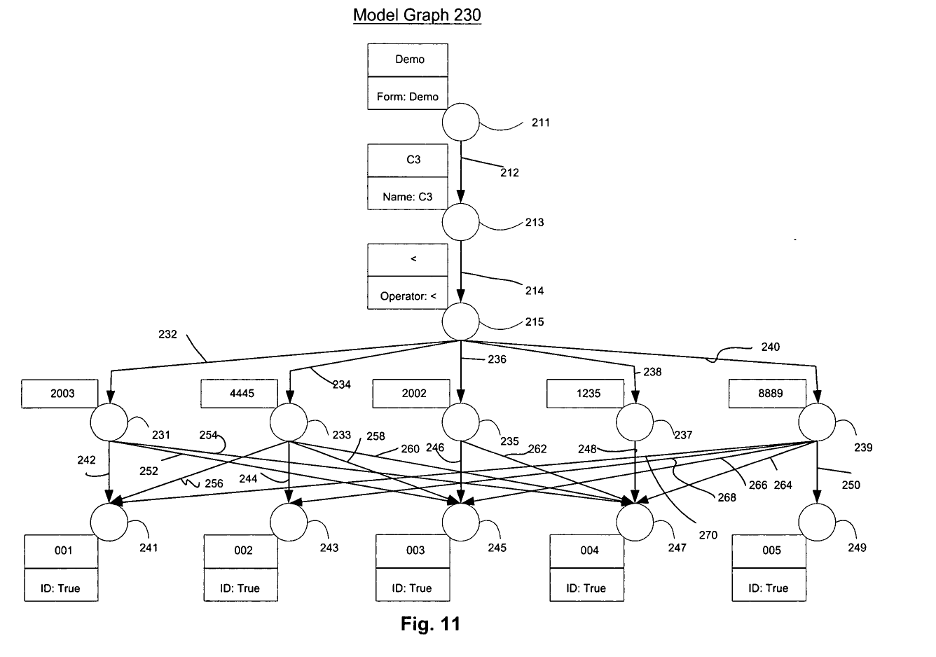

A further example of the generalization method will also be described. FIG. 9 shows an exemplary set of form data Demo 200 which is part of an application to be tested. The form Demo 200 has two fields, field C1 202 containing the entry ID for each of the entries and field C3 204 which is a numeric field. There are five entries (001, 002, 003, 004 and 005) in the form Demo 200.

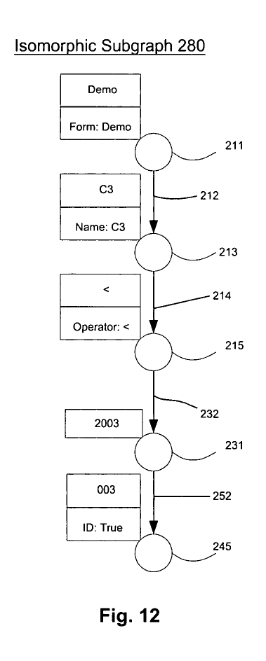

In this example, the captured real usage data APIs are associated with the application operation C3<2000. Referring to the form data Demo 200, it can be seen that such an operation would return one valid entry 004. FIG. 10 shows the pattern graph 210 representation of the operation C3<2000. The node 211 is the root node and has the value Demo and the property Form:Demo. The edge 212 points to the node 213 which is the first child node with the node value C3 and the property Name:C3. The edge 214 points to the node 215 which has a node value of <and the property operator:<. The edge 216 points to the node 217 which has a value of 2000. The node 217 does not have any node property since it is merely a variable that is used in the operation. The edge 218 points to the final node 219 which is the valid result of the operation having the node value of the entry 004 and the property ID:true.

A valid alternative for this operation would have to ensure that at least one entry is associated with it. However, in this example, there is no direct mapping between the data in the form data Demo 200 and the data which represents a valid alternative in the context of generalization. The construction of the model graph requires the inference of valid alternatives based on the operator and the sample data. Thus, since the operator in this example is (<), an increase in the variable (2000) of the operation is guaranteed to include at least one entry.

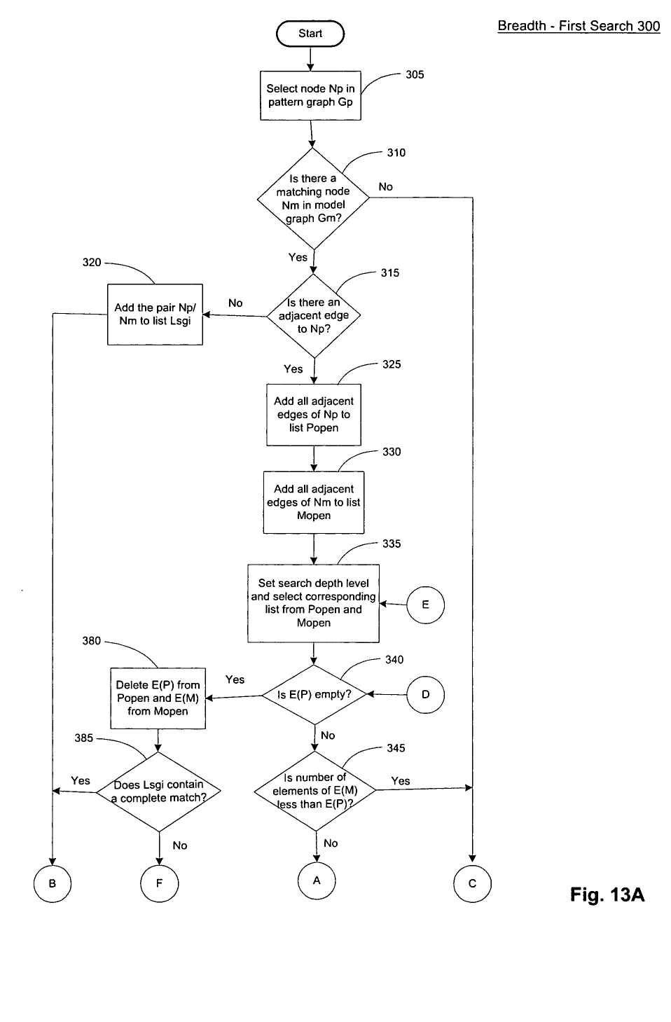

FIG. 11 shows an exemplary model graph 230 of valid alternatives to the pattern graph 210. The model graph 230 contains some of the same nodes and edges as the pattern graph 210, e.g., nodes 211, 213 and 215 and edges 212 and 214. As described above, the alternatives were inferred based on the operator node 215 (<) and the data in form data Demo 200. As described above, the operator < means that at least one valid entry will exist if the operation variable is increased from the original variable (2000). However, the generalization method also looks at the form data Demo 200 to determine an optimal selection of possible alternatives.

In this example, an optimal selection of alternatives was to increase the variable (2000) to a value which was one greater than each of the values C3 204 for the entries. Therefore, a first alternative was shown as the edge 232 leading to node 231 having the value 2003 which is one greater than the C3 204 value of 2002 in the form data Demo 200. The result of this alternative is the return of three entries from the form data Demo 200, i.e., the edge 242 leading to the node 241 for entry 001, the edge 252 leading to the node 245 for entry 003, and the edge 254 leading to the node 247 for entry 004. As can be seen from the form data Demo 200 each of these entries has a C3 204 value that is less than the alternative variable value of 2003.

The example continues with other alternative variables as shown by the edge 234 leading to the node 233 (value 4445) which results in four valid alternatives, e.g., the edge 244 leading to the node 243 for entry 002, the edge 256 leading to the node 241 for entry 001, the edge 258 leading to the node 245 for entry 003, and the edge 260 leading to the node 247 for entry 004. Another alternative variable is shown by the edge 236 leading to the node 235 (value 2002) which results in two valid alternatives, e.g., the edge 246 leading to the node 245 for entry 003 and the edge 262 leading to the node 247 for entry 004. The edge 238 leads to the node 237 (value 1235) which results in one valid alternative, e.g., the edge 248 leading to the node 247 for entry 004. The final alternative is shown by the edge 240 leading to the node 239 (value 8889) which results in five valid alternatives, e.g., the edge 250 leading to the node 249 for entry 005, the edge 264 leading to the node 247 for entry 004, the edge 266 leading to the node 245 for entry 003, the edge 268 leading to the node 243 for entry 002, and the edge 270 leading to the node 241 for entry 001.

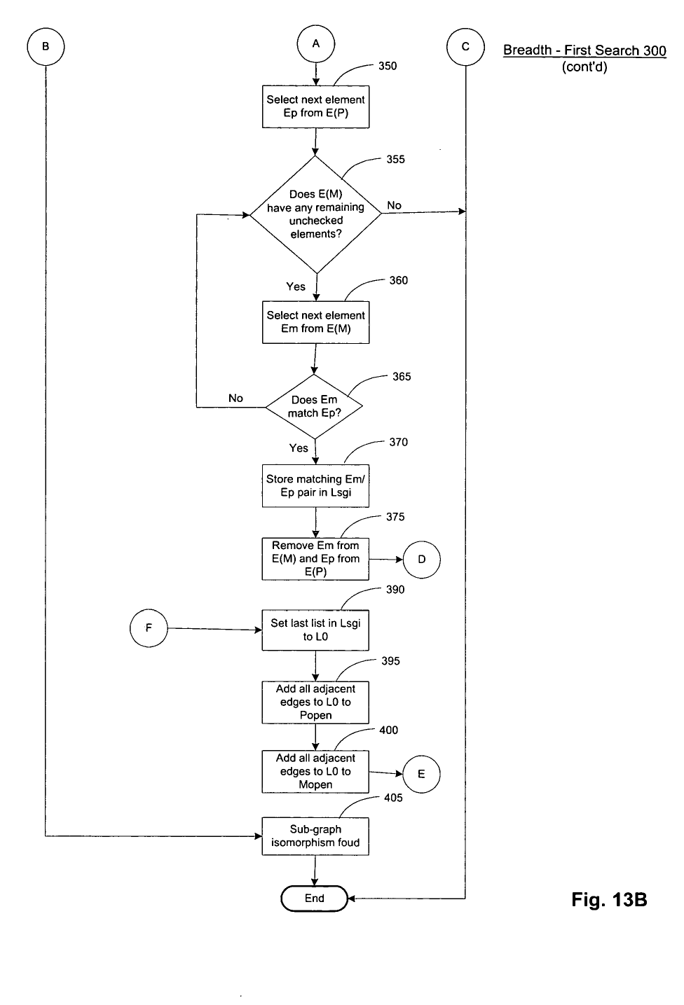

The valid isomorphic sub-graphs may then be extracted from the model graph 230 to form the virtual tasks to be used in the stress test. FIG. 12 shows one exemplary isomorphic sub-graph 280 which may be extracted from the model graph 230. In this example the isomorphic sub-graph 280 represents the virtual task for an operation C3<2003 which returns a result of true for entry 004. Each of the nodes 211, 213, 215, 231 and 245 and the edges 212, 214, 232 and 252 are included as part of the model graph 230 as shown in FIG. 11. This virtual task is equivalent to the original task for the operation C3<2000 as shown in pattern graph 210 of FIG. 10. Thus, the virtual task as represented by the isomorphic sub-graph 280 may be a virtual task that is used in the stress test of the application.

It will be apparent to those skilled in the art that various modifications and variations can be made in the structure and the methodology of the present invention, without departing from the spirit or scope of the invention. Thus, it is intended that the present invention cover the modifications and variations of this invention provided they come within the scope of the appended claims and their equivalents.

1. A method, comprising the steps of:
generating a usage task from usage data;
constructing a pattern graph from the usage task;
constructing a model graph which represents a space of equivalents to the usage task represented by the pattern graph; and
extracting sub-graphs from the model graph, wherein each of the extracted sub-graphs is isomorphic to the pattern graph.

2. The method according to claim 1, further comprising the step of:
capturing the usage data from a user session.

3. The method according to claim 2, wherein the capturing step includes one of retrieving a log file of an application program and intercepting user calls to the application program.

4. The method according to claim 1, wherein the usage data includes API calls.

5. The method according to claim 1, wherein the generating task includes the sub-step of:
separating the usage data into generalizable entities and non-generalizable entities, wherein the pattern graph is constructed using only the generalizable entities.

6. The method according to claim 5, wherein the pattern graph construction step includes the sub-step of:
creating a fully qualified name for each of the generalizable entities, the fully qualified name including a local entity name and an associative qualifier.

7. The method according to claim 6, wherein the pattern graph construction step further includes the sub-steps of:
merging each fully qualified name into a node of the pattern graph; and
merging each of the associative qualifiers into an edge of the pattern graph.

8. The method according to claim 1, wherein the pattern graph is a directed acyclic graph.

9. The method according to claim 1, wherein the model graph is a directed acyclic graph.

10. The method according to claim 1, wherein the model graph retains all the dependencies of the pattern graph.

11. The method according to claim 1, further comprising the step of:
creating virtual tasks from each of the extracted sub-graphs.

12. The method according to claim 11, further comprising the step of:
performing a stress-test on an application program using the virtual tasks.

13. The method according to claim 1, wherein the model graph construction step includes the sub-step of:
determining an equivalent model graph node by matching node properties of a pattern graph node to node properties of a model graph node.

14. The method according to claim 1, wherein the extraction step includes the sub-step of:
performing one of a breadth-first search and a depth-first search of the model graph.

15. A system, comprising:
a pattern graph construction module configured to construct a pattern graph from a usage task;
a model graph construction module configured to construct a model graph which represents a space of equivalents to the usage task represented by the pattern graph; and
an extraction module configured to extract sub-graphs from the model graph, wherein each of the extracted sub-graphs is isomorphic to the pattern graph.

16. The system according to claim 15, wherein the pattern graph includes nodes and edges.

17. The system according to claim 16, wherein each of the nodes includes a node label, the node label including a set of node properties for each of the nodes.

18. The system according to claim 17, wherein the node label is null.

19. The system according to claim 16, wherein each of the nodes includes a node value.

20. The system according to claim 16, wherein each of the edges is directed to reflect the ordering of the nodes.

21. The system according to claim 16, wherein the model graph also includes nodes and edges, wherein each of the nodes of the model graph is equivalent to at least one of the nodes of the pattern graph and each of the edges of the model graph is equivalent to at least one of the edges of the pattern graph.

22. The system according to claim 16, wherein an equivalent model graph node is determined by matching node properties of one of the pattern graph nodes.

23. The method according to claim 15, wherein the pattern graph is a directed acyclic graph.

24. The method according to claim 15, wherein the model graph is a directed acyclic graph.

25. The method according to claim 15, wherein the model graph retains all the dependencies of the pattern graph.

26. A computer-readable storage medium storing a set of instructions, the set of instructions capable of being executed by a processor, the set of instructions performing the steps of:
generating a usage task from usage data;
constructing a pattern graph from the usage task;
constructing a model graph which represents a space of equivalents to the usage task represented by the pattern graph; and
extracting sub-graphs from the model graph, wherein each of the extracted sub-graphs is isomorphic to the pattern graph.
